(19) United States
(12) Patent Application Publication
(10) Pub. No.: US 2024/0258106 A1
(43) Pub. Date: Aug. 1, 2024

(54) SUBSTRATE PROCESSING FOR AlN AND GaN POLARITY CONTROL

(71) Applicant: Applied Materials, Inc., Santa Clara, CA (US)

(72) Inventor: Michel Khoury, Mountain View, CA (US)

(73) Assignee: Applied Materials, Inc., Santa Clara, CA (US)

(21) Appl. No.: 18/162,074

(22) Filed: Jan. 31, 2023

(51) Int. Cl. H01L 21/02; H01L 29/20

(52) U.S. Cl. CPC H01L 21/0254; H01L 21/02381; H01L 21/02458; H01L 21/02488; H01L 21/02502; H01L 29/2003

(57) ABSTRACT

The present technology includes semiconductor structures. Structures include a silicon-containing substrate, a layer of metal nitride overlying the silicon-containing substrate, a structure overlying the layer of the metal nitride, and an oxygen rich layer disposed between the layer of the metal nitride and the structure. The structure is formed from a material that includes a gallium-containing material, and aluminum nitride material, or a combination thereof, where at least about 90 wt. % of the material exhibits a metal-polarity.

### TECHNICAL FIELD

The present technology relates to semiconductor processing and materials. More specifically, the present technology relates to formation processes and materials for light-emitting diode structures, power devices, RF devices, and other semiconductor structures and components thereof.

### BACKGROUND

Semiconductor structures containing metal-nitrides are finding increased importance in the development and fabrication of short wavelength light emitting diodes (LEDs), laser diodes (LDs), and electronic devices including high power, high frequency, radio frequency, and high temperature transistors and integrated circuits. As one example, LED panels or devices may be formed with a number of light sources that operate as pixels on the device. The pixels may be formed with monochromatic light sources that are then delivered through a conversion layer to produce color, or the pixels may each have individual color light sources formed. In either scenario, any number up to millions of light sources may be formed and connected for operation. While there have been considerable developments to semiconductor structures, producing the structures may still be prone to defects causing reduced performance.

Thus, there is a need for improved systems and methods that can be used to produce high quality devices and structures. These and other needs are addressed by the present technology.

### SUMMARY

Embodiments of the present technology are generally directed to a semiconductor structure. Embodiments include a silicon-containing substrate, a layer of metal nitride overlying the silicon-containing substrate, an oxygen rich layer formed on the layer of the metal nitride, where the oxygen rich layer is an inversion domain generally aligned with a surface of the layer of metal nitride, and a structure overlying the oxygen rich layer. The structure is formed from a material that includes a gallium-containing material, and aluminum nitride material, or a combination thereof, where at least about 90 wt. % of the material exhibits a metal-polarity.

In embodiments, the layer of metal nitride includes a nitride of aluminum, hafnium, niobium, titanium, scandium, gallium, or combinations thereof. In more embodiments, the layer of metal nitride having the oxygen rich layer formed thereon includes a plurality of features. In further embodiments, the oxygen rich layer includes aluminum, oxygen, and nitrogen. Additionally or alternatively, the oxygen rich layer includes aluminum, oxygen, nitrogen, and silicon. In more embodiments, the oxygen rich layer comprises an oxygen rich material of the general formula AlₓO_{y}N_{z}. In additional embodiments, the silicon-containing substrate is silicon.

Furthermore, in embodiments, the material is gallium-nitride, and greater than or about 95 wt. % of the gallium-nitride exhibits a metal polarity. In more embodiments, the layer of metal nitride has a surface area, and the oxygen rich layer is disposed over greater than or about 85% of the surface area. Moreover, in embodiments, the oxygen rich layer is disposed over greater than or about 95% of the surface area. In further embodiments, the seed layer includes a nitride formed by physical vapor deposition.

Embodiments of the present technology are also generally directed to a semiconductor structure. The semiconductor structure includes a silicon substrate, a layer of aluminum nitride, hafnium nitride, niobium nitride, titanium nitride, scandium nitride, gallium nitride, or a combination thereof, formed by physical vapor deposition, overlying the silicon substrate, an oxygen rich layer formed on the layer of aluminum nitride, hafnium nitride, niobium nitride, titanium nitride, scandium nitride, gallium nitride, or a combination thereof, and a structure overlying the oxygen rich layer. The structure is formed from a material that includes a gallium-containing material, an aluminum nitride material, or a combination thereof, where at least about 90 wt. % of the material exhibits a metal polarity. The oxygen rich layer contains at least two of oxygen, nitrogen, aluminum, and gallium. In embodiments, the layer of aluminum nitride, hafnium nitride, niobium nitride, or a combination thereof having an oxygen rich layer formed thereon includes a plurality of features.

Embodiments of the present technology are also generally directed to a method of semiconductor processing. The method includes forming a seed layer of a metal nitride material over a silicon substrate. The method includes exposing the seed layer to an oxygen rich environment having at least 23.5 vol. % oxygen based upon the volume of the environment. The method also includes forming a polarity inversion domain and forming a gallium-containing material, an aluminum containing material, or a combination thereof on the polarity inversion domain, where at least about 90 wt. % of the material exhibits a metal-polarity.

In embodiments, the oxygen rich environment includes generating a plasma of an oxygen-containing precursor and contacting the seed layer with plasma effluents of the oxygen-containing precursor. In more embodiments, the seed layer is contacted with the oxygen rich environment for a period of time greater than or about 1 minute. In additional or alternative embodiments, the seed layer is formed by physical vapor deposition. In further embodiments, the oxygen rich material includes two or more of oxygen, aluminum, nitrogen, and gallium. In yet more embodiments, wherein the gallium-containing material, aluminum containing material, or combination thereof, are formed over a plurality of features.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows selected operations in a method of forming a semiconductor structure according to some embodiments of the present technology.

FIGS. 3A-3C illustrate schematic views of a device developed according to some embodiments of the present technology.

FIG. 4A shows a TEM dark field image of a conventional semiconductor structure.

FIG. 4B shows a TEM dark field image of a semiconductor structure according to embodiments of the present technology.

FIG. 4C shows a SEM image of a conventional semiconductor structure.

FIG. 4D shows a SEM image of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Semiconductor structures, such as short wavelength light emitting diodes (LEDs), laser diodes (LDs), and electronic devices including high power, high frequency, radio frequency, and high temperature transistors and integrated circuits, suffer from formation defects, such as threading dislocations. Namely, dislocations and defects in the thick nitride film can cause decreases in device efficiency or may result in interoperability of the device. As one example, LEDs may include semiconductor structures that emit light when current flows through the structure. Electrons in the semiconductor may recombine with electron holes, releasing energy in the form of photons. Many conventional LEDs are formed with a thick film, such as thicker than a micron, which may define quantum wells. Dislocations, such as threading dislocations or defects, may propagate through the material in the quantum well, such as from the underlying substrate, and may result in non-radiative recombination in the quantum well region, where the LED emits a phonon instead of a photon. Threading dislocations in conventional technologies may readily pass through to the surface of the quantum well, which may undesirably increase the non-radiative recombination. These dislocations may form or exist due to a number of aspects related to the growth or structural formation process, and the dislocations may carry through the subsequent device layers formed, including the LED active region, which may further reduce the efficiency of the device.

Conventional technologies may utilize complex and expensive processing operations to develop the quantum well material in an attempt to reduce dislocations and may be limited to specific materials and processes for the structure. For example, metal-oxide chemical vapor deposition may be used to form both a seed layer over a substrate, as well as the subsequent material used for the quantum well. This process may be expensive and time consuming. However, conventional technologies have been incapable of utilizing alternative techniques to produce the seed layer, and dislocation density may still be unfavorably high. For example, physical vapor deposition may produce films characterized by reduced structural or film characteristics, which may prevent adequate growth of the quantum well material. As one non-limiting example, gallium nitride may be used as the quantum well material in some devices, and conventional technologies have been unable to grow this material on metal nitride seed layers produced by physical vapor deposition, which may be characterized by more poorly oriented crystal structures.

Namely, due to the structure of the metal nitride seed layer produced, the polar gallium nitride material may form crystals characterized by mixed polarity, with regions of gallium-polar growth (metal-polar growth) and regions of nitrogen-polar growth. This may prevent the structure from appropriately coalescing to form a quantum well, and the device may fail. For instance, structures with mixed polarity gallium-containing material layers exhibit poor surface qualities, such as haziness and dislocations, which render the structure unusable for semiconductor processing. Many efforts have been made to correct the polarity of the gallium-containing material layers, including treatment of the substrate prior to incorporation of the seed layer. However, conventional processes have been unable to consistently produce highly ordered gallium-containing material layers of predominantly single polarity, particularly when formed on physical vapor deposited seed layers.

The present technology may overcome issues associated with conventional technologies and may cure or otherwise overcome the previous limitations of physical vapor deposition nitride materials. By performing one or more oxygenation treatments on a physical vapor deposition seed layer for a preselected time, an oxygen rich layer may be produced, which provides for growth of substantially all metal-polar crystals on the oxygen rich layer. Accordingly, dislocations or defects may be controlled or minimized, which may improve device quality and performance. Although the remaining disclosure will routinely identify specific LED materials and processes utilizing the disclosed technology, it will be readily understood that the systems and methods are equally applicable to a variety of materials and processes as may occur for producing displays. Accordingly, the technology should not be considered to be so limited as for use with LED processes alone. After discussing an exemplary chamber system that may be used according to some embodiments of the present technology, methods for producing high-quality structures will be described.

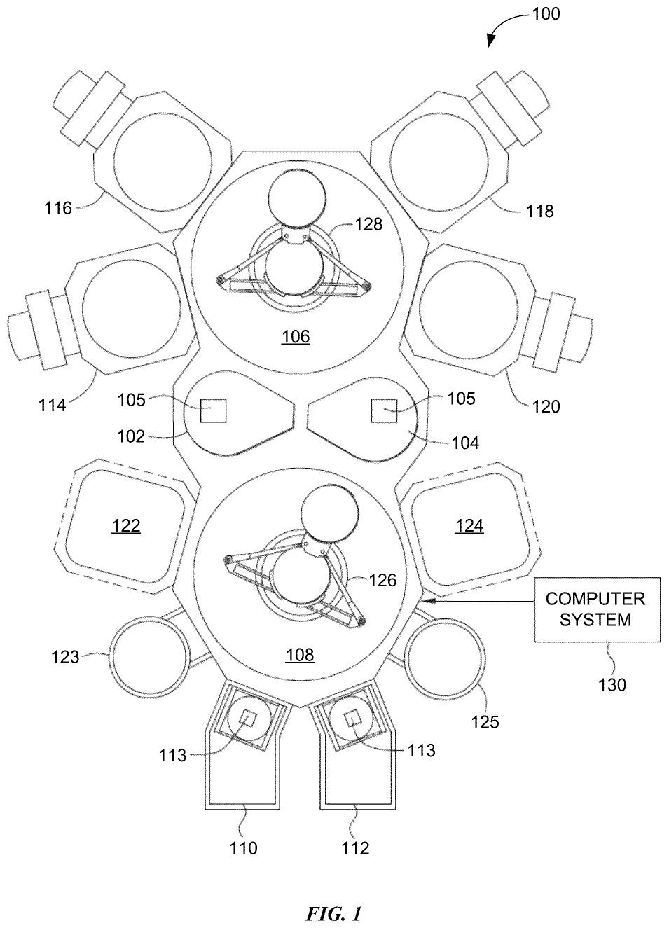

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

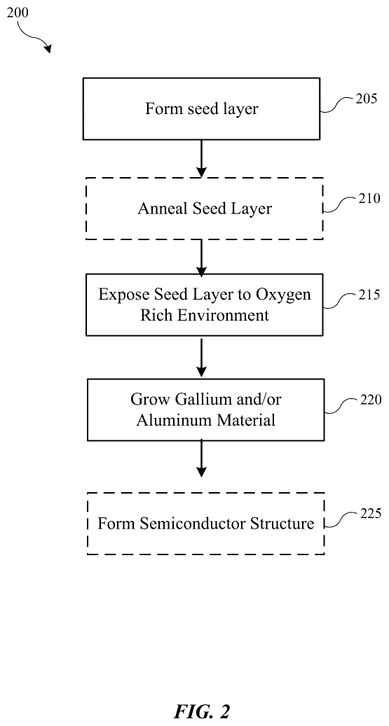

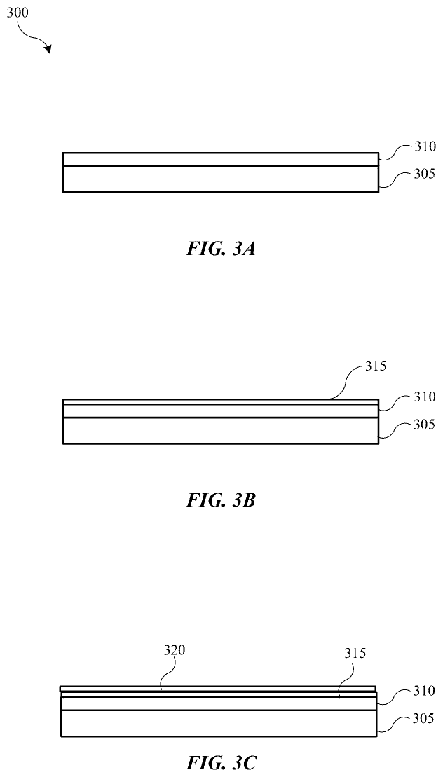

FIG. 2 illustrates selected operations of a semiconductor processing method 200. Method 200 may include one or more operations prior to the initiation of the method, including front end processing, deposition, etching, polishing, cleaning, or any other operations that may be performed prior to the described operations. For example, in some embodiments a degas or other preparatory operation may be performed on a substrate, such as silicon or sapphire substrate, to prepare the substrate for deposition. The method may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 200 describes operations shown schematically in FIGS. 3A-3C, the illustrations of which will be described in conjunction with the operations of method 200. It is to be understood that the figures illustrate only partial schematic views, and a substrate may contain any number of sections having aspects as illustrated in the figures, as well as alternative structural aspects that may still benefit from aspects of the present technology.

Method 200 may involve optional operations to develop the structure to a particular fabrication operation. As illustrated in FIG. 3A, a substrate 305 may be used to facilitate formation of a number of structures utilized in LED formation or other semiconductor processing. Although only two aspects are illustrated, it is to be understood that a substrate may have hundreds, thousands, millions, or more aspects, and which may be of any size. Substrate 305 may be any substrate on which structures may be formed, such as silicon-containing materials, aluminum materials, including sapphire, or any other materials as may be used in display or semiconductor fabrication. The substrate 305 may have various dimensions, such as 200 mm or 300 mm diameter wafers, as well as rectangular or square panels. The substrate 305 may be cleaned or processed in preparation for depositing one or more layers of material on the substrate for producing a structure, such as an LED, for example, although any number of other semiconductor structures may similarly benefit from aspects of the present technology.

In embodiments, the substrate 305 provided may undergo an optional pre-clean layer prior to deposition thereon. For instance, in embodiments, a plasma assisted etch process, a reactive etch or clean process, the like, or a combination thereof may be conducted in order to remove any byproducts formed on the substrate. In embodiments, an optional preclean may be conducted via a Siconi™ etch process, or any reactive etch or clean process known in the art. For instance, such a pre-clean may be selected to remove silicon nitride formed on an upper surface of a substrate, as an example only. Nonetheless, in embodiments, a substrate 305 may be loaded into load lock 110,112 and transferred to a preclean chamber (such as process chamber 114) via robots 106, 108.

A nitrogen-containing nucleation or seed layer 310 may be formed overlying the substrate 305 at operation 205, such as by transferring the substrate to process chamber 118. Although the remaining disclosure will regularly discuss formation on or with an aluminum nitride seed layer, it is to be understood that the technology is not so limited. In some embodiments, the seed layer may be or include gallium nitride, niobium nitride, hafnium nitride, aluminum nitride, aluminum gallium nitride, or any other metal nitride on which gallium-containing materials, other materials, or combinations thereof may be formed. Seed layer 310 may be formed in any number of ways, such as by metal-oxide chemical vapor deposition. Although, as discussed above, in some embodiments, the seed layer may be formed by physical vapor deposition without the negative effects normally associated with physical vapor deposition seed layers. Moreover, in embodiments, the physical vapor deposition may be conducted at high temperatures, such as a temperature of greater than or about 400° C., and may be performed at a temperature of greater than or about 500° C.

Namely, as noted above, conventional technologies have been incapable of utilizing physical vapor deposition for seed layer formation because the produced material is typically characterized by disorientation of the structure. Physical vapor deposition formation of the seed layer may provide unfavorable kinetics for metal nitride growth, which may lead to any number of issues. The incompatible interface produced between the seed layer and subsequently formed gallium materials facilitates greater transmission of defects, as well as production of mixed polarity gallium nitride, which may detrimentally reduce efficiency and quality of the quantum well. Accordingly, conventional technologies have been constrained to utilizing more expensive and more complex technologies, such as e-beam or metal-oxide chemical vapor deposition. The present technology may overcome these issues by performing one or more techniques that may create an oxygen rich layer where a continuous oxygen rich material is formed, which provides the necessary growth conditions for formation of highly ordered and substantially exclusive metal-polar gallium-containing material layers.

Regardless of the method of formation, in embodiments, the metal-nitride seed layer may be predominantly nitrogen-polar such that at least about 50 wt. % or more of the seed layer exhibits a nitrogen polarity, such as greater than or about 60 wt. %, such as greater than or about 70 wt. %, such as greater than or about 75 wt. %, such as greater than or about 80 wt. %, such as greater than or about 85 wt. %, such as greater than or about 90 wt. %, such as greater than or about 95 wt. %, such as greater than or about 97.5 wt. %, such as greater than or about 99 wt. %, or any ranges or values therebetween.

Nonetheless, in embodiments, the seed layer may optionally include one or more inner layers, where an inner layer directly contacts the substrate 305, and may be a metal layer or a metal nitride layer. In such embodiments, the substrate may be transferred to a process chamber 116 after the optional pre-clean, where process chamber 116 may be a deposition chamber, such as a physical vapor deposition, atomic layer deposition, plasma-enhanced chemical vapor deposition, chemical vapor deposition, or the like chamber, suitable for depositing one or more metal layers directly over the substrate. In embodiments the one or more inner metal layers may be formed from aluminum, hafnium, niobium, titanium, scandium, gallium, combinations thereof, or the like. It should be understood that the method may include depositing one or more of the above metals according to the above processes, but that remaining nitrogen in the chamber atmosphere may initiate formation of a metal nitride. Thus, in embodiments, while a metal layer is deposited, the inner layer may be a metal layer, a metal nitride layer, a silicon nitride layer, or a combination thereof. In embodiments, the deposited metal layer may include a metal that is utilized to form the metal nitride layer, which will be discussed in greater detail below. Nonetheless, when utilized, the inner metal layer may have a thickness of less than or about 5 nm, such as less than or about 4 nm, such as less than or about 3 nm, such as less than or about 2 nm, such as less than or about 1 nm, or any ranges or values therebetween.

When an inner metal layer is utilized, it should be understood that the inner layer of the seed layer may directly overlie the silicon substrate, and an outer aluminum nitride seed layer may directly overlie the inner layer. Nonetheless, it should be understood that, in embodiments, the seed layer only includes one or more outer layers, such as one or more aluminum nitride seed layers which directly or indirectly overly the substrate.

Method 200 may include an optional annealing of the seed layer at operation 210. The anneal may be performed at high temperatures, which may improve the crystalline structure of the nitride seed layer, including at an exposed surface, and which may help to reduce or limit transmission of dislocations through the subsequently formed layers, and may facilitate improved growth of gallium materials. The anneal may be performed at a temperature of greater than or about 1,000° C., and may be performed at a temperature of greater than or about 1,150° C., greater than or about 1,200° C., greater than or about 1,250° C., greater than or about 1,300° C., greater than or about 1,350° C., greater than or about 1,400° C., greater than or about 1,450° C., greater than or about 1,500° C., greater than or about 1,550° C., greater than or about 1,600° C., or higher. However, depending on the substrate material, a lower temperature may be used, which may facilitate treatment of the nitride seed layer, but may protect the substrate. For example, in some embodiments, the substrate may be silicon, which may be damaged or melt at higher temperatures. Accordingly, in some embodiments, and depending on the substrate, the temperature may be maintained at less than or about 1,500° C. and may be maintained at less than or about 1,400° C., less than or about 1,300° C., or less.

The anneal may be performed for a period of time sufficient to improve the seed layer, and the anneal may be performed for greater than or about 30 minutes, greater than or about 60 minutes, greater than or about 90 minutes, greater than or about 120 minutes, greater than or about 150 minutes, greater than or about 180 minutes, or more. The time period may be related to the anneal temperature, where a higher temperature anneal may be performed for a reduced period of time, while producing similar effects. For example, while an anneal at 1,600° C. may be performed for a time period of less than or about 30 minutes, an anneal performed at a temperature of less than or about 1,200° C. may be performed for greater than or about 90 minutes. The anneal may be performed in any processing atmosphere, but in some embodiments the anneal may be performed in an inert atmosphere, such as a nitrogen atmosphere, an argon atmosphere, a helium atmosphere, among other non-reactive, oxygen-deprived, or other inert materials. However, as discussed above, it should be understood that, in embodiments, no annealing is necessary due to the formation of the oxygen rich layer discussed herein.

Namely, subsequent formation of the seed layer, and optional anneal step, the substrate with the (optionally annealed) seed layer is treated with oxygen, such as in an oxygen rich environment at operation 215, which may occur in a dedicated oxygen chamber, such as a plasma oxygen chamber in process chamber 120. In such embodiments, the substrate may be transferred to process chamber 120 after formation of the seed layer. In embodiments, the oxygen treatment may include an oxygen rich environment having greater than or about 23.5% oxygen by volume based upon the volume of the environment, such as greater than or about 25%, such as greater than or about 30%, such as greater than or about 40%, such as greater than or about 50%, such as greater than or about 60%, such as greater than or about 70%, such as greater than or about 80%, such as greater than or about 90%, such as up to even a 100% oxygen by volume atmosphere, or any ranges or values therebetween. In embodiments, it should be understood that the environment defining the total volume may be a chamber, such as a process chamber discussed above.

In embodiments, the substrate containing the seed layer formed thereon may be exposed to the oxygen rich environment for at least about 15 seconds or more, such as greater than or about 30 seconds, such as greater than or about 1 minute, such as greater than or about 5 minutes, such as greater than or about 10 minutes, such as greater than or about 15 minutes, such as greater than or about 30 minutes, or any ranges or values therebetween.

In embodiments, the seed layer may be exposed to an oxygen rich environment by purging all or a portion of an atmosphere in one or more process chambers discussed above to obtain the necessary volume percent of oxygen in the atmosphere according to any one or more of the above values or ranges.

Additionally, or alternatively, the oxygen rich environment may be achieved by exposing the seed layer to an oxygen plasma treatment. During the plasma exposure, oxygen radicals or plasma effluents may be generated and delivered to the substrate. The plasma effluents may contact the seed layer and form an oxygen rich layer or material regions as previously described. The exposure may incorporate oxygen into the structure being developed. The process may include generation of oxygen plasma either locally or remotely from a processing region in which a substrate is disposed. The plasma may be generated from any oxygen-containing material such as diatomic oxygen, ozone, nitrous oxide, nitric oxide, or any other oxygen-containing material, and in some embodiments, ozone may be used with or without plasma generation. In such a manner, the oxygen plasma can replace the precursor and interact with the seed layer to form an oxide on a surface of the seed layer.

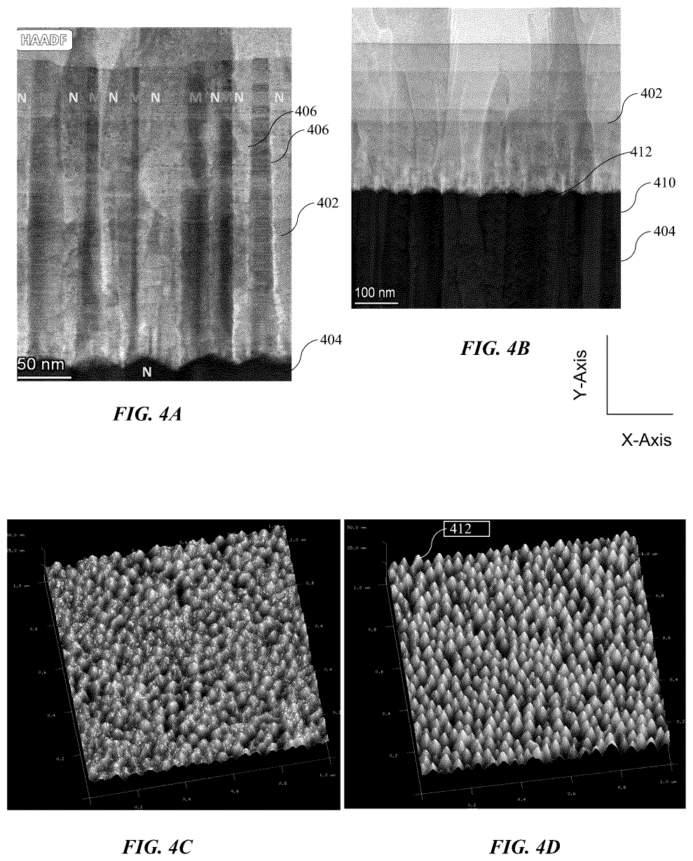

The present technology has found that by utilizing an oxygen rich environment to form an oxide layer over the seed layer, a horizontal inversion domain may be formed generally aligned with and/or parallel to the seed layer surface (e.g. 410 in FIG. 4B, namely the surface adjacent to gallium-containing material layer 402). Furthermore, a highly consistent and homogenous oxygen rich layer can be formed over the seed layer. For instance, in embodiments, the seed layer may defined a surface area, and the oxygen rich layer can be formed over or on at least about 85% of the surface area, such as greater than or about 87.5%, such as greater than or about 90%, such as greater than or about 92.5%, such as greater than or about 95%, such as greater than or about 97.5%, or any ranges or values therebetween. Thus, while such an oxygen rich layer may only be one to a few angstroms in thickness, the layer may be substantially continuous over the surface of the seed layer.

Moreover, the present technology has surprisingly found that the process and layers of the present technology allow for the formation of beneficial aspects, allowing high quality semiconductor materials to be formed, even when utilizing physical vapor deposited seed layers. Namely, the oxygen rich layer according to the present technology forms a highly homogeneous and robust oxygen rich layer that allows for a full domain inversion (e.g., from nitrogen-polar, or mixed polarity to predominantly or exclusively metal-polar), and formation of a largely single-polarity gallium-containing material layer thereon, which is not present on seed layers only exposed to atmospheric oxygen. For instance, referring to FIGS. 4A and 4B, FIG. 4A illustrates a TEM dark field image of a seed layer exposed to atmospheric oxygen prior to formation of the gallium-containing quantum well layer over the seed layer, but that was not exposed to an oxygen rich environment according to the present technology. As shown in FIG. 4A, alternating metal-polarity (M) and nitrogen polarity (N) vertically extending (y-direction) inversion domains 406 are present throughout the gallium-containing material 402 formed on seed layer 404. Conversely, FIG. 4B shows a TEM dark field image of a seed layer exposed to an oxygen rich environment according to the present technology. As shown in FIG. 4B no vertically extending inversion domains are present, as the gallium-containing material layer is formed from substantially all metal-polarity crystals over the oxygen rich layer 410 that serves as a horizontal inversion domain (x-direction). In embodiments, the inversion domain formed from the oxygen rich material 410 may extend along the surface of the seed layer and is therefore considered to be generally aligned with or parallel to a surface of the seed layer. As illustrated, in embodiments, the layers may be generally aligned or parallel even when a plurality of discrete features 412 are formed on the gallium-containing material 402.

The surprising features of the seed layer containing an oxygen rich layer according to the present technology is further illustrated by FIGS. 4C and 4D. Namely, FIG. 4C illustrates a SEM image of a seed layer exposed to atmospheric oxygen prior to formation of the gallium-containing quantum well layer over the seed layer, but that was not exposed to an oxygen rich environment according to the present technology. As illustrated, the surface is textured, but has few to no individually defined features. Without wishing to be bound by theory, it is believed that the lack of features (likely caused at least in part by a mixed polarity seed layer surface) forms poor and irregular nucleation sites for formation of a quantum well material. Conversely, as illustrated in FIG. 4D, which shows a SEM photograph of a seed layer exposed to an oxygen rich environment according to the present technology, a plurality of defined cone or pyramid like features 412 are formed by the oxygen rich material coated seed layer.

Thus, in embodiments, the oxygen rich layer coated seed layer may contain a plurality of discrete, spaced apart, cone or pyramidal like features that extend over substantially the entire seed layer surface. In embodiments, the features may extend over at least about 85% of the seed layer surface area, such as greater than or about 87.5%, such as greater than or about 90%, such as greater than or about 92.5%, such as greater than or about 95%, such as greater than or about 97.5%, or any ranges or values therebetween. Furthermore, as illustrated, in embodiments, at least about 60%, such as greater than or about 65%, such as greater than or about 70%, such as greater than or about 75%, such as greater than or about 80%, such as greater than or about 85%, such as greater than or about 90%, such as greater than or about 95%, or more of the features may have a height and/or width within about 25% of an average height and/or width, such as within about 20%, such as within about 15%, such as within about 10%, or any ranges or values therebetween.

Nonetheless, the oxygen-rich layer may include one or more of aluminum, oxygen, gallium, or nitrogen. The layer may also be characterized by any number of crystal structures, which may improve the growth characteristics of gallium nitride. For example, gallium nitride may be characterized by a hexagonal crystal structure, which exhibits improved growth on single-polarity structures. Thus, embodiments of the present disclosure may show improved gallium-containing material growth even on substrates such as silicon, which were previously viewed as unsuitable when utilized with physical vapor deposited seed layers. In addition, the present technology has found that a robust oxygen rich layer improves grown of subsequent layer. Thus, in embodiments, no etching or removal of the oxygen rich layer occurs prior to growth of a gallium-containing material.

Oxygen rich materials that may remain may include any of the elements noted above and may have at least some regions characterized by a more aluminum oxide nature, which may be characterized by one or more crystalline structures. For example, oxygen rich materials that may be formed by the oxidation may be characterized by any number of aluminum oxide crystal structures, such as alpha-aluminum oxide, gamma-aluminum oxide, delta-aluminum oxide, theta-aluminum oxide, iota-aluminum oxide, kappa-aluminum oxide, or sigma-aluminum oxide. The formation may produce any number of lattice parameters of any of these materials and may provide any number of crystal structures. For example the oxide or material formed may be characterized by features that may relate to a hexagonal crystal structure, a cubic crystal structure, a tetragonal crystal structure, a monoclinic crystal structure, and/or an orthorhombic crystal structure.

Nonetheless, in embodiments, the oxygen rich material may be an aluminum oxynitride material. In embodiments, the oxygen rich material may have a general formula AlₓO_{y}N_{z}. In embodiments, x may be a value such that aluminum forms at least about 50% of the aluminum oxynitride, such as greater than or about 55%, such as greater than or about 60%, such as greater than or about 65%, such as greater than or about 70%, such as up to about 75%, or any ranges or values therebetween. Moreover, in embodiments, y may be a value such that oxygen forms at least about 50% of the aluminum oxynitride, such as greater than or about 55%, such as greater than or about 60%, such as greater than or about 65%, such as greater than or about 70%, such as up to about 75%, or any ranges or values therebetween. Furthermore, in embodiments, z may be a value such that nitrogen forms less than about 50% of the aluminum oxynitride, such as less than or about 40%, such as less than or about 35%, such as less than or about 30%, such as less than or about 25%, such as less than or about 20%, or any ranges or values therebetween.

In embodiments where the substrate may be removed from a vacuum environment, the substrate may be delivered back to a processing environment, where a quantum well material, such as a gallium-containing material may be grown at operation 220. The gallium-containing material, which may include gallium nitride, for example, may be grown by metal-oxide chemical vapor deposition, or by any other deposition or formation process. FIG. 3C, illustrates the gallium-containing material 320 as a layer, but it should be understood that the gallium-containing material 320 may be characterized by discrete regions of a pyramidal shaped structures, mirroring the structures 412 discussed above, although the process may facilitate growth of any structure including a continuous layer of gallium-containing material. The gallium-containing material is grown overlying the oxygen rich layer overlying the seed layer, which may facilitate growth of the gallium-containing material with a metal-polarity and reduced dislocations extending through the materials.

Nonetheless, while the quantum well material has thus far been described as a gallium-containing material. It should be understood that, in some embodiments a different metal-nitride, such as aluminum-nitride, indium-nitride, or the like, may be used instead, or may be utilized as an intermediate between the oxygen-rich layer and the gallium-layer. However, it should be understood that in embodiments, no intermediate layer is needed for improved metal-nitride growth according to the present technology, as the oxygen rich layer provides for a polarity inversion domain, forming a substantially exclusive metal-polarity inversion domain that improves the metal-polarity growth of the subsequent layer.

For instance, in embodiments, at least about 90 wt. % of the gallium-containing material exhibits a metal-polarity based on the weight of the gallium-containing material, such as greater than or about 92.5 wt. %, such as greater than or about 95 wt. %, such as greater than or about 97.5 wt. %, such as greater than or about 98 wt. %, such as greater than or about 99 wt. %, or any ranges or values therebetween.

By performing treatments according to some embodiments of the present technology, dislocation density through the gallium-containing material may be reduced. For example, the present technology may produce regions of gallium nitride of any thickness, such as from dozens of nanometers to several micrometers or more, and which may be characterized by a dislocation density of less than or about 8.0 E⁹/cm², and which may be characterized by a dislocation density of less than or about 7.5 E⁹/cm², less than or about 7.0 E⁹/cm², less than or about 6.5 E⁹/cm², less than or about 6.0 E⁹/cm², less than or about 5.5 E⁹/cm², less than or about 5.0 E⁹/cm², or less. This may improve efficiency of operation and may improve device performance.

After forming the gallium-nitride material, method 200 may further include forming a semiconductor structure at optional operation 230, such as in embodiments in which the gallium-nitride material may be used as a quantum well for a semiconductor structure. Embodiments of forming a semiconductor structure may include forming a p-doped layer over the gallium-containing material. The p-doped layer may be made from one or more of gallium nitride, aluminum-indium-gallium-nitride, indium-gallium-nitride, and aluminum-gallium nitride. In some embodiments, the p-doped layer may include gallium-free, indium-and-nitride materials such as indium nitride, and aluminum-indium-nitride, among other gallium-free nitride materials. Forming the semiconductor structure may additionally include forming contact pads on the layers of the structure. The contact pads may be formed of one or more electrically conductive materials such as copper, aluminum, tungsten, chromium, nickel, silver, gold, platinum, palladium, titanium, tin, and/or indium, among other conductive materials. Any additional or alternative operations or processes for forming a semiconductor structure may be included, as one of skill would appreciate.

As discussed above, in embodiments, the semiconductor structure may include a LED structure. Thus, as an example, LED formation may also include forming a light conversion region on the LED structure. The light conversion region may absorb the light emitted by the LED structure and emit light at a longer wavelength from an LED display. In some embodiments, the light conversion region may be a quantum-dot layer, which may be operable to convert a shorter wavelength of light from the LED structure into one of red, green, or blue light. Additional quantum-dot layers may be formed on other LED structures to convert the shorter wavelength of light emitted by the LED structure into another of the red, green, and blue colored light. In some embodiments, combinations of three quantum-dot layers on three LED structures may form an LED pixel that includes subpixels operable to emit red, green, and blue light. In some embodiments, sequential operations may form a red quantum dot layer in one of the subpixels of each LED pixel, a green quantum dot layer in another one of the subpixels, and a blue quantum dot layer in still another one of the subpixels. Following the formation of the blue quantum dot, each LED pixel in the array of LED pixels may include red, green, and blue subpixels.

Embodiments of the present technology include operations and structures that reduce or limit the amount of threading dislocations extending through the quantum well, which may otherwise reduce efficiency and performance of the resulting structure. By treating seed layers and forming an oxygen rich layer as described above, the present technology may allow improved metal-polarity gallium-containing material growth, which may limit the prevalence and extension of dislocations through the materials. Accordingly, embodiments of the present technology may provide fabrication methods and resulting structures characterized by reduced amounts of threading dislocation for the improved efficiency of light-emitting diodes or other semiconductor structures.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either limit of the range, both limits of the range, or neither limit of the range are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor structure comprising:
a silicon-containing substrate;
a layer of a metal nitride overlying the silicon-containing substrate;
an oxygen rich layer formed on the layer of the metal nitride, wherein the oxygen rich layer is an inversion domain generally aligned with a surface of the layer of the metal nitride; and
a structure overlying the oxygen rich layer, the structure being formed from a material comprising a gallium-containing material, an aluminum nitride material, or a combination thereof, wherein at least about 90 wt. % of the material exhibits a metal-polarity.

2. The semiconductor structure of claim 1, wherein the layer of the metal nitride comprises a nitride of aluminum, hafnium, niobium, titanium, scandium, gallium, or combinations thereof.

3. The semiconductor structure of claim 1, wherein the layer of the metal nitride having the oxygen rich layer formed thereon comprises a plurality of discrete features.

4. The semiconductor structure of claim 2, wherein the oxygen rich layer comprises aluminum and oxygen.

5. The semiconductor structure of claim 4, wherein the oxygen rich layer further comprises nitrogen and/or silicon.

6. The semiconductor structure of claim 5, wherein the oxygen rich layer comprises an oxygen rich material of a general formula AlₓO_{y}N_{z}.

7. The semiconductor structure of claim 1, wherein the silicon-containing substrate is silicon.

8. The semiconductor structure of claim 1, wherein the material is gallium-nitride, and wherein greater than or about 95 wt. % of the gallium-nitride exhibits a metal-polarity.

9. The semiconductor structure of claim 5, wherein the layer of the metal nitride has a surface area, and wherein the oxygen rich layer is formed on greater than or about 85% of the surface area.

10. The semiconductor structure of claim 9, wherein the oxygen rich layer is formed on greater than or about 95% of the surface area.

11. The semiconductor structure of claim 10, wherein greater than about 50 wt. % of the layer of metal nitride exhibits a nitrogen-polarity.

12. The semiconductor structure of claim 8, wherein the layer of the metal nitride comprises a nitride formed by physical vapor deposition.

13. A semiconductor structure comprising:
a silicon substrate;
a layer of aluminum nitride, hafnium nitride, niobium nitride, titanium nitride, scandium nitride, gallium nitride, or a combination thereof, formed by physical vapor deposition, overlying the silicon substrate;
an oxygen rich layer formed on the layer of aluminum nitride, hafnium nitride, niobium nitride or a combination thereof, the oxygen rich layer containing at least two of oxygen, nitrogen, aluminum, and gallium
a structure overlying the oxygen rich layer, the structure being formed from a material comprising a gallium-containing material, an aluminum nitride material, or a combination thereof, wherein at least about 90 wt. % of the material exhibits a metal-polarity.

14. The semiconductor structure of claim 13, wherein the layer of aluminum nitride, hafnium nitride, niobium nitride or a combination thereof having the oxygen rich layer formed thereon comprises a plurality of discrete features.

15. A method of semiconductor processing comprising:
forming a seed layer of a metal nitride material on a silicon substrate;
exposing the seed layer to an oxygen rich environment having at least 23.5 vol. % oxygen based upon a volume of the environment;
forming a polarity inversion domain over the seed layer; and
forming a gallium-containing material, an aluminum containing material, or a combination thereof on the inversion domain, wherein at least about 90 wt. % of the material exhibits a metal-polarity.

16. The method of semiconductor processing of claim 15, wherein the oxygen rich environment comprises generating a plasma of an oxygen-containing precursor and contacting the seed layer with plasma effluents of the oxygen-containing precursor.

17. The method of semiconductor processing of claim 15, wherein the seed layer is contacted with the oxygen rich environment for a period of time greater than or about 1 minute.

18. The method of semiconductor processing of claim 15, wherein the seed layer is formed by physical vapor deposition.

19. The method of semiconductor processing of claim 15, wherein the polarity inversion domain comprises two or more of oxygen, aluminum, nitrogen, and gallium.

20. The method of semiconductor processing of claim 15, wherein the gallium-containing material, aluminum containing material, or combination thereof are formed over a plurality of discrete features.
